(19) United States
(12) Patent Application Publication
(10) Pub. No.: US 2026/0182007 A1
(43) Pub. Date: Jun. 25, 2026

(54) SEMICONDUCTOR ELEMENT

(71) Applicant: DENSO CORPORATION, Kariya-shi (JP)

(72) Inventor: Jun OKAWARA, Kariya-shi (JP)

(21) Appl. No.: 19/544,177

(22) Filed: Feb. 19, 2026

Related U.S. Application Data
(63) Continuation of application No. PCT/JP2024/032396, filed on Sep. 10, 2024.

(30) Foreign Application Priority Data
Nov. 24, 2023 (JP) 2023-199137

(51) Int. Cl. H10D 84/00; H10D 12/00

(52) U.S. Cl. CPC H10D 84/161; H10D 12/481

(57) ABSTRACT

A semiconductor element includes a semiconductor substrate having: an IGBT region that overlaps with a collector region; and a diode region that overlaps with a cathode region. Inter-trench semiconductor regions include a hole injection restriction structure having: an n-type barrier region in contact with a body region from below; and a pillar region that extends from the barrier region to an emitter electrode and in Schottky contact with the emitter electrode. The IGBT region has a boundary region formed by the inter-trench semiconductor regions located between a main region and the diode region. The hole injection restriction structure is provided in the inter-trench semiconductor regions within the diode region and the boundary region.

### CROSS REFERENCE TO RELATED APPLICATIONS

The present application is a continuation application of International Patent Application No. PCT/JP2024/032396 filed on September 10, 2024, which designated the U.S. and claims the benefit of priority from Japanese Patent Application No. 2023-199137 filed on November 24, 2023. The entire disclosures of all of the above applications are incorporated herein by reference.

### TECHNICAL FIELD

The technology disclosed in this specification relates to a semiconductor element.

### BACKGROUND

A semiconductor element has an IGBT (Insulated Gate Bipolar Transistor) and a diode. Plural trenches are provided on the upper surface of the semiconductor substrate, across the IGBT region and the diode region.

### SUMMARY

According to an aspect of the present disclosure, a semiconductor element includes: a semiconductor substrate; an emitter electrode in contact with an upper surface of the semiconductor substrate; and a collector electrode in contact with a lower surface of the semiconductor substrate. The semiconductor substrate has: a p-type collector region in contact with the collector electrode; and an n-type cathode region in contact with the collector electrode. When the semiconductor substrate is viewed in the thickness direction, an area overlapping with the collector region is an IGBT region, and an area overlapping with the cathode region is a diode region. A first direction is defined along the boundary between the IGBT region and the diode region on the upper surface. A second direction is defined to extend from the IGBT region toward the diode region on the upper surface. Trenches extending in the first direction are provided on the upper surface, and arranged at interval in the second direction.

The inner surface of each of the trenches is covered with a trench insulating film. A trench electrode is disposed within each of the trenches. Inter-trench semiconductor regions between the trenches are arranged in each of the IGBT region and the diode region. Each of the inter-trench semiconductor regions in the IGBT region and the diode region has a p-type body region in contact with the emitter electrode and the trench insulating film. At least a portion of the inter-trench semiconductor region in the IGBT region has an n-type emitter region in contact with the emitter electrode and in contact with the trench insulating film above the body region. The semiconductor substrate has an n-type drift region distributed across the IGBT region and the diode region and disposed below the body region. A part of the inter-trench semiconductor regions has a hole injection restriction structure including an n-type barrier region in contact with the body region from below, and a pillar region that extends from the barrier region to the emitter electrode and in Schottky contact with the emitter electrode. The IGBT region has a main region formed by the inter-trench semiconductor regions in which the hole injection restriction structure is not provided, and a boundary region formed by the inter-trench semiconductor regions located between the main region and the diode region. The hole injection restriction structure may be provided in each of the inter-trench semiconductor regions in the diode region and the boundary region.

### BRIEF DESCRIPTION OF DRAWINGS

FIG. 1 is a plan view of a semiconductor element according to a first embodiment.

FIG. 2 is a cross-sectional view taken along line II-II in FIG. 1.

FIG. 3 is a graph showing a relationship between a value W/T and a recovery charge Qrr.

FIG. 4 is a cross-sectional view of a semiconductor element according to a second embodiment.

FIG. 5 is a cross-sectional view of a semiconductor element according to a third embodiment.

FIG. 6 is a cross-sectional view of a semiconductor element according to a modification.

FIG. 7 is a cross-sectional view of a semiconductor element according to a fourth embodiment.

FIG. 8 is a cross-sectional view of a semiconductor element according to a modification.

### DETAILED DESCRIPTION

A semiconductor element has an IGBT (Insulated Gate Bipolar Transistor) and a diode. Plural trenches are provided on the upper surface of the semiconductor substrate, across the IGBT region and the diode region. A trench insulating film and a trench electrode are disposed in each of the trenches. The trench electrode is insulated from the semiconductor substrate by the trench insulating film. The trench electrode in the IGBT region functions as a gate electrode. In a range including the upper surface of the semiconductor substrate, a p-type body region and an n-type drift region are provided across the IGBT region and the diode region. The drift region is in contact with the body region from below. A channel is formed in the body region within the IGBT region. The body region within the diode region functions as an anode. In addition, a p-type collector region is provided below the drift region in the IGBT region. An n-type cathode region is provided below the drift region within the diode region. Furthermore, a hole injection restriction structure is provided in a semiconductor region between the trenches (hereinafter referred to as an inter-trench semiconductor region). The hole injection restriction structure has an n-type barrier region in contact with the body region from below, and an n-type pillar region that extends from the barrier region to the emitter electrode. The pillar region is in Schottky contact with the emitter electrode. The hole injection restriction structure is provided over the IGBT region and the diode region. The hole injection restriction structure restricts the injection of holes from the body region into the drift region when the diode is turned on. Therefore, when the diode performs a recovery operation, the recovery current is restricted.

In the semiconductor device, the hole injection restriction structure is provided entirely over the IGBT region and the diode region. When the hole injection restriction structure is provided in the IGBT region, it is possible to restrict the injection of holes from the body region into the drift region at the boundary between the IGBT region and the diode region. When the hole injection restriction structure is provided entirely over the IGBT region, leakage current is more likely to occur within the IGBT region. This specification proposes a technique for effectively restricting hole injection into the drift region by providing the hole injection restriction structure partially in the IGBT region.

According to a first aspect of the present disclosure, a semiconductor element includes: a semiconductor substrate; an emitter electrode in contact with an upper surface of the semiconductor substrate; and a collector electrode in contact with a lower surface of the semiconductor substrate. The semiconductor substrate has: a p-type collector region in contact with the collector electrode; and an n-type cathode region in contact with the collector electrode. When the semiconductor substrate is viewed in the thickness direction, the area overlapping with the collector region is an IGBT region, and the area overlapping with the cathode region is a diode region. A first direction is defined along the boundary between the IGBT region and the diode region on the upper surface. A second direction is defined to extend from the IGBT region toward the diode region on the upper surface. Trenches extending along the first direction are provided on the upper surface, and arranged at interval in the second direction. The inner surface of each of the trenches is covered with a trench insulating film. A trench electrode is disposed within each of the trenches. Inter-trench semiconductor regions between the trenches are arranged in each of the IGBT region and the diode region. Each of the inter-trench semiconductor regions in the IGBT region and the diode region has a p-type body region in contact with the emitter electrode and the trench insulating film. At least a portion of the inter-trench semiconductor region in the IGBT region has an n-type emitter region in contact with the emitter electrode and in contact with the trench insulating film above the body region. The semiconductor substrate has an n-type drift region distributed across the IGBT region and the diode region and disposed below the body region. A part of the inter-trench semiconductor regions has a hole injection restriction structure including an n-type barrier region in contact with the body region from below, and a pillar region that extends from the barrier region to the emitter electrode and in Schottky contact with the emitter electrode. The IGBT region has a main region formed by the inter-trench semiconductor regions in which the hole injection restriction structure is not provided, and a boundary region formed by the inter-trench semiconductor regions located between the main region and the diode region. The hole injection restriction structure is provided in each of the inter-trench semiconductor regions in the diode region and the boundary region. A width of the boundary region in the second direction is 80% or more of the thickness of the semiconductor substrate.

When the width of the boundary region is 80% or more of the thickness of the semiconductor substrate, the injection of holes into the drift region can be effectively restricted, and the reverse recovery current of the diode can be effectively restricted.

In the semiconductor element of the first aspect, a work function at an interface between the pillar region and the emitter electrode in the boundary region may be lower than a work function at an interface between the pillar region and the emitter electrode in the diode region.

This configuration makes it possible to more effectively restrict the injection of holes into the drift region in the boundary region.

In the semiconductor element of the first aspect, each of the trench electrodes in the main region may be a gate electrode. At least one trench electrode in the boundary region may be a dummy electrode connected to the emitter electrode.

According to a second aspect of the present disclosure, a semiconductor element includes a semiconductor substrate, an emitter electrode in contact with an upper surface of the semiconductor substrate, and a collector electrode in contact with a lower surface of the semiconductor substrate. The semiconductor substrate has a p-type collector region in contact with the collector electrode, and an n-type cathode region in contact with the collector electrode. When the semiconductor substrate is viewed in the thickness direction, an area overlapping with the collector region is an IGBT region, and an area overlapping with the cathode region is a diode region. A first direction is defined along a boundary between the IGBT region and the diode region on the upper surface, and a second direction is defined to extend from the IGBT region toward the diode region on the upper surface. Trenches extending in the first direction are provided on the upper surface, and arranged at interval in the second direction. The inner surface of each trench is covered with a trench insulating film. A trench electrode is disposed within each of the trenches. Inter-trench semiconductor regions interposed between the trenches are arranged in each of the IGBT region and the diode region. Each of the inter-trench semiconductor regions in the IGBT region and the diode region has a p-type body region in contact with the emitter electrode and the trench insulating film. At least a portion of the inter-trench semiconductor regions in the IGBT region has an n-type emitter region in contact with the emitter electrode and in contact with the trench insulating film above the body region. The semiconductor substrate has an n-type drift region distributed across the IGBT region and the diode region and disposed below the body region. A portion of the inter-trench semiconductor regions has a hole injection restriction structure including an n-type barrier region in contact with the body region from below, and a pillar region that extends from the barrier region to the emitter electrode and in Schottky contact with the emitter electrode. The IGBT region has a main region formed by the inter-trench semiconductor regions in which the hole injection restriction structure is not provided, and a boundary region formed by the inter-trench semiconductor regions located between the main region and the diode region. The hole injection restriction structure is provided in each of the inter-trench semiconductor regions in the diode region and the boundary region. A work function at the interface between the pillar region and the emitter electrode in the boundary region is lower than a work function at the interface between the pillar region and the emitter electrode in the diode region.

This configuration effectively restricts the injection of holes into the drift region in the boundary region.

According to a third aspect of the present disclosure, a semiconductor element includes a semiconductor substrate, an emitter electrode in contact with an upper surface of the semiconductor substrate, and a collector electrode in contact with a lower surface of the semiconductor substrate. The semiconductor substrate has a p-type collector region in contact with the collector electrode, and an n-type cathode region in contact with the collector electrode. When the semiconductor substrate is viewed in the thickness direction, an area overlapping with the collector region is an IGBT region, and an area overlapping with the cathode region is a diode region. A first direction is defined along the boundary between the IGBT region and the diode region on the upper surface, and a second direction is defined to extend from the IGBT region toward the diode region on the upper surface. Trenches extending along the first direction are provided on the upper surface, and arranged at interval in the second direction. The inner surface of each trench is covered with a trench insulating film. A trench electrode is disposed within each of the trenches. Inter-trench semiconductor regions interposed between the trenches are arranged in each of the IGBT region and the diode region. Each of the inter-trench semiconductor regions in the IGBT region and the diode region has a p-type body region in contact with the emitter electrode and the trench insulating film. At least a portion of the inter-trench semiconductor regions in the IGBT region has an n-type emitter region in contact with the emitter electrode and in contact with the trench insulating film above the body region. The semiconductor substrate has an n-type drift region distributed across the IGBT region and the diode region and disposed below the body region. A portion of the inter-trench semiconductor regions has a hole injection restriction structure including an n-type barrier region in contact with the body region from below, and a pillar region that extends from the barrier region to the emitter electrode and in Schottky contact with the emitter electrode. A portion of the inter-trench semiconductor regions has a floating structure in which the upper surface is covered with an interlayer insulating film. The IGBT region has a main region formed by the inter-trench semiconductor regions in which the hole injection restriction structure is not provided, and a boundary region formed by the inter-trench semiconductor regions located between the main region and the diode region. Each of the inter-trench semiconductor regions in the diode region has the hole injection restriction structure. Each of the inter-trench semiconductor regions within the boundary region includes the hole injection restriction structure or/and the floating structure.

This configuration effectively restricts the injection of holes into the drift region in the boundary region.

### First Embodiment

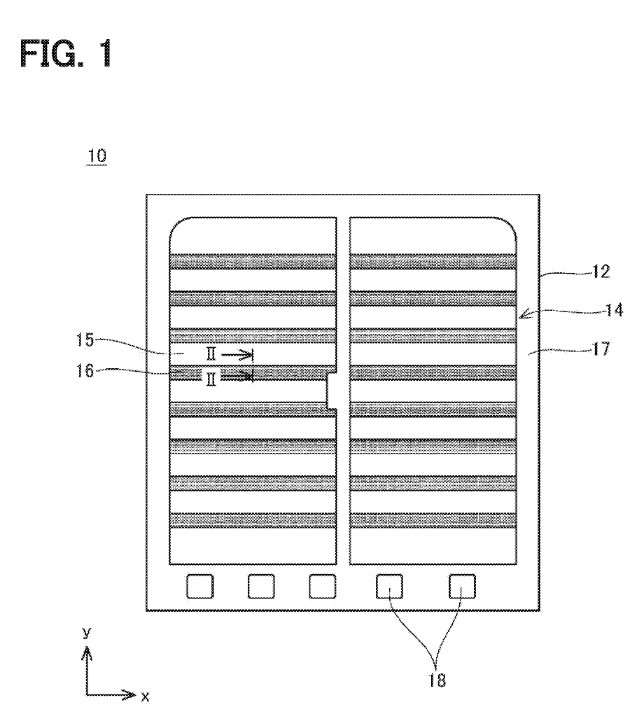

As shown in FIG. 1, a semiconductor element 10 of a first embodiment has a semiconductor substrate 12 made of silicon. When viewed from above, as shown in FIG. 1, the semiconductor substrate 12 has an element portion 14 and a peripheral portion 17. The element portion 14 has plural IGBT regions 15 and plural diode regions 16. An IGBT is provided in the IGBT region 15, and a diode is provided in the diode region 16. Each of the IGBT regions 15 and the diode regions 16 has a rectangular shape that is long in the x direction. The IGBT regions 15 and the diode regions 16 are alternately arranged in the y direction. Therefore, the boundary between the IGBT region 15 and the diode region 16 extends in the x direction. Although not shown, the peripheral portion 17 is provided with a pressure-resistant structure such as a guard ring. Furthermore, signal electrode pads 18 are provided on the peripheral portion 17. One of the signal electrode pads 18 is a gate pad that controls the gate voltage of the IGBT.

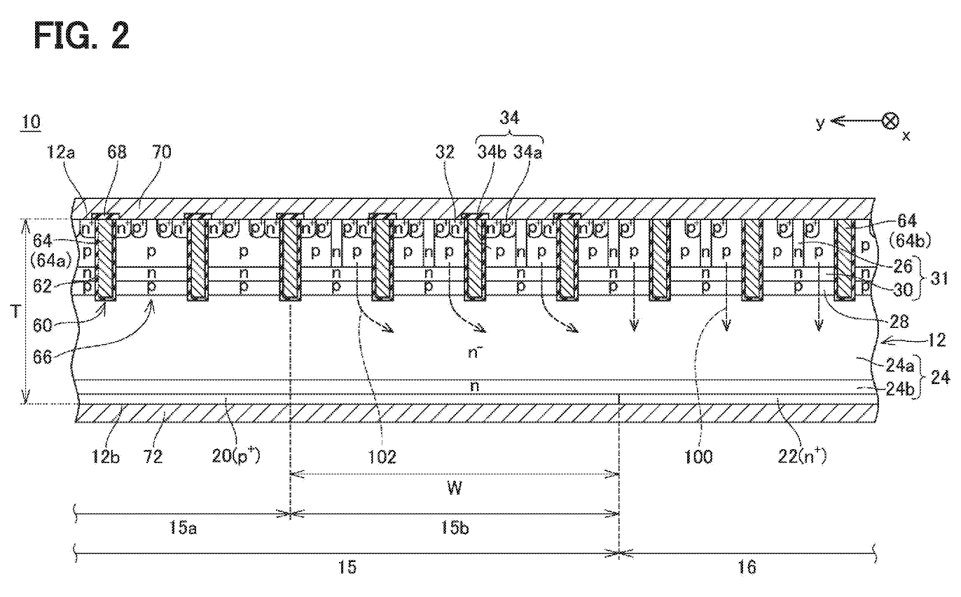

FIG. 2 shows a cross-section of the semiconductor element 10 taken along the y direction in a range across the IGBT region 15 and the diode region 16. A p-type collector region 20 and an n-type cathode region 22 are disposed in an area including the lower surface 12b of the semiconductor substrate 12. The collector region 20 is provided in the IGBT region 15, and the cathode region 22 is provided in the diode region 16. In other words, when the semiconductor substrate 12 is viewed in the thickness direction, the region overlapping with the collector region 20 is the IGBT region 15, and the region overlapping with the cathode region 22 is the diode region 16.

Plural trenches 60 are formed on the upper surface 12a of the semiconductor substrate 12. In the upper surface 12a of the semiconductor substrate 12, each of the trenches 60 extends longitudinally in the x direction. In the upper surface 12a of the semiconductor substrate 12, the trenches 60 are arranged at interval in the y direction. The trenches 60 are provided in each of the IGBT region 15 and the diode region 16. Hereinafter, an area of the semiconductor region in the semiconductor substrate 12 that is interposed between the two trenches 60 will be referred to as an inter-trench semiconductor region 66. The inter-trench semiconductor regions 66 are provided in each of the IGBT region 15 and the diode region 16. The inner surface of each of the trenches 60 is covered with a trench insulating film 62. A trench electrode 64 is disposed inside each of the trenches 60. The trench electrode 64 is insulated from the semiconductor substrate 12 by the trench insulating film 62.

An interlayer insulating film 68 and an emitter electrode 70 are provided on the upper portion of the semiconductor substrate 12. The interlayer insulating film 68 covers the upper surface of the trench electrode 64 in the IGBT region 15. The emitter electrode 70 is made of a metal (for example, an AlSi alloy). The emitter electrode 70 is provided across the IGBT region 15 and the diode region 16, and covers the upper surface 12a and the interlayer insulating film 68. The trench electrode 64 in the IGBT region 15 is insulated from the emitter electrode 70 by the interlayer insulating film 68. Although not shown, the trench electrode 64 in the IGBT region 15 is connected to a gate pad by a wiring. The trench electrode 64 in the IGBT region 15 is a gate electrode 64a whose potential can be changed by a gate pad. The trench electrode 64 in the diode region 16 is connected to the emitter electrode 70. The trench electrode 64 in the diode region 16 is a dummy electrode 64b that is fixed to the same potential as the emitter electrode 70.

A collector electrode 72 is provided on the lower portion of the semiconductor substrate 12. The collector electrode 72 is provided across the IGBT region 15 and the diode region 16, and covers the lower surface 12b. The collector region 20 and the cathode region 22 are in ohmic contact with the collector electrode 72.

Each of the inter-trench semiconductor regions 66 in the IGBT region 15 and the diode region 16 has a p-type upper body region 34. The upper body region 34 is in contact with the emitter electrode 70 and also in contact with the trench insulating film 62 on the side surface of the trench 60. The upper body region 34 has a contact region 34a and a low concentration region 34b having a p-type impurity concentration lower than that of the contact region 34a. The contact region 34a is disposed at a position including the upper surface 12a and is in ohmic contact with the emitter electrode 70. The low concentration region 34b is in contact with the contact region 34a from below. The low concentration region 34b is in contact with the trench insulating film 62 on the side surface of the trench 60.

Each of the inter-trench semiconductor regions 66 in the IGBT region 15 has an n-type emitter region 32. The emitter region 32 is disposed at a position including the upper surface 12a and is in ohmic contact with the emitter electrode 70. The emitter region 32 is in contact with the trench insulating film 62 on the side surface of the trench 60. The low concentration region 34b is in contact with the emitter region 32 from below. The emitter region 32 is in contact with the trench insulating film 62 above the low concentration region 34b. In this embodiment, the emitter region 32 is not provided in the diode region 16, but the emitter region 32 may be provided in the diode region 16.

Each of the inter-trench semiconductor regions 66 in the IGBT region 15 and the diode region 16 has an n-type barrier region 30. The n-type impurity concentration of the barrier region 30 is lower than the n-type impurity concentration of the emitter region 32. The barrier region 30 is disposed below the low concentration region 34b. The barrier region 30 is in contact with the trench insulating film 62 on the side surface of the trench 60.

Each of the inter-trench semiconductor regions 66 in the IGBT region 15 and the diode region 16 has a p-type lower body region 28. The p-type impurity concentration of the lower body region 28 is lower than the p-type impurity concentration of the contact region 34a. The lower body region 28 is disposed below the barrier region 30. The lower body region 28 is in contact with the trench insulating film 62 on the side surface of the trench 60. The lower body region 28 is separated from the upper body region 34 by the barrier region 30. In other words, the barrier region 30 separates the p-type body region into the upper body region 34 and the lower body region 28.

The IGBT region 15 has a main region 15a and a boundary region 15b. The boundary region 15b is located adjacent to the diode region 16 and includes plural inter-trench semiconductor regions 66. The main region 15a is disposed at a position separated from the diode region 16 in the y direction, and includes plural inter-trench semiconductor regions 66. In other words, the region between the main region 15a and the diode region 16 is the boundary region 15b. An n-type pillar region 26 is provided in each of the inter-trench semiconductor regions 66 in the diode region 16 and the boundary region 15b. No pillar region 26 is provided in the inter-trench semiconductor region 66 in the main region 15a. In other words, the region adjacent to the diode region 16 and composed of the plural inter-trench semiconductor regions 66 having the pillar region 26 is the boundary region 15b. The region located away from the diode region 16 and composed of the plural inter-trench semiconductor regions 66 not having the pillar region 26 is the main region 15a. The n-type impurity concentration of the pillar region 26 is lower than the n-type impurity concentration of the emitter region 32. The pillar region 26 extends from the barrier region 30 to the emitter electrode 70. The pillar region 26 is in Schottky contact with the emitter electrode 70. Hereinafter, the set of the barrier region 30 and the pillar region 26 will be referred to as a hole injection restriction structure 31. The hole injection restriction structure 31 is provided in each of the inter-trench semiconductor regions 66 in the diode region 16 and the boundary region 15b. The hole injection restriction structure 31 is not provided in the inter-trench semiconductor region 66 in the main region 15a.

The semiconductor substrate 12 has an n-type intermediate region 24. The intermediate region 24 is distributed across the IGBT region 15 and the diode region 16. The intermediate region 24 is disposed between the upper structure (i.e., the upper body region 34, the emitter region 32, the barrier region 30, the lower body region 28) and the lower structure (i.e., the collector region 20, the cathode region 22) of the semiconductor substrate 12. The intermediate region 24 includes a drift region 24a and a buffer region 24b.

The drift region 24a is an n-type region having a lower n-type impurity concentration than the barrier region 30 and the pillar region 26. The drift region 24a is distributed across the IGBT region 15 and the diode region 16. The drift region 24a is disposed below the upper body region 34, the barrier region 30, and the lower body region 28. The drift region 24a is in contact with the lower body region 28 from below. The drift region 24a is in contact with the trench insulating film 62 at the bottom end of the trench 60.

The buffer region 24b is an n-type region having an n-type impurity concentration higher than that of the drift region 24a and lower than that of the cathode region 22. The buffer region 24b is distributed across the IGBT region 15 and the diode region 16. The buffer region 24b is in contact with the drift region 24a from below. The buffer region 24b is in contact with the collector region 20 and the cathode region 22 from above.

In FIG. 2, the boundary region 15b has a width W in the y direction, and a thickness T represents the thickness of the semiconductor substrate 12. In the first embodiment, the width W is 80% or more of the thickness T.

An IGBT is formed in the IGBT region 15. When a potential higher than that of the emitter electrode 70 is applied to the collector electrode 72, the IGBT switches. When a potential higher than the gate threshold is applied to the gate electrode 64a, a channel is formed in the upper body region 34 and the lower body region 28 in the area adjacent to the trench insulating film 62. This turns on the IGBT, causing a current to flow from the collector electrode 72 to the emitter electrode 70. When the potential of the gate electrode 64a is reduced to a potential lower than the gate threshold, the channel disappears and the IGBT is turned off.

A diode is formed in the diode region 16. When a higher potential than that of the collector electrode 72 is applied to the emitter electrode 70, holes are injected from the upper body region 34 into the drift region 24a in the diode region 16, as indicated by an arrow 100 in FIG. 2. Then, the electrical resistance of the drift region 24a decreases due to the conductivity modulation. Therefore, electrons flow from the collector electrode 72 to the emitter electrode 70 via the cathode region 22, the buffer region 24b, the drift region 24a, the lower body region 28, the barrier region 30, and the upper body region 34. That is, the diode turns on. Furthermore, when the diode is in an on-state, holes are injected from the upper body region 34 into the drift region 24a even in the boundary region 15b adjacent to the diode region 16, as indicated by an arrow 102. However, in the first embodiment, the hole injection restriction structure 31 restricts the injection of holes into the drift region 24a. That is, in the hole injection restriction structure 31, the barrier region 30 is connected to the emitter electrode 70 having a low potential by the pillar region 26, and therefore the potential of the barrier region 30 is low. This restricts the injection of holes from the upper body region 34 into the drift region 24a. Since the hole injection restriction structure 31 is provided between the diode region 16 and the boundary region 15b, the injection of holes into the drift region 24a is restricted between the diode region 16 and the boundary region 15b. That is, the injection of holes indicated by the arrow 100, 102 is restricted.

When the potential applied to the emitter electrode 70 is switched to a potential lower than that of the collector electrode 72 while the diode is in an on-state, the diode performs a recovery operation. That is, when holes present in the drift region 24a are discharged to the emitter electrode 70, a reverse current (so-called recovery current) flows instantaneously through the diode. In the first embodiment, when the diode is on, the injection of holes into the drift region 24a is restricted by both the diode region 16 and the boundary region 15b, so that fewer holes are discharged from the drift region 24a to the emitter electrode 70 during recovery operation. Therefore, recovery current is unlikely to occur.

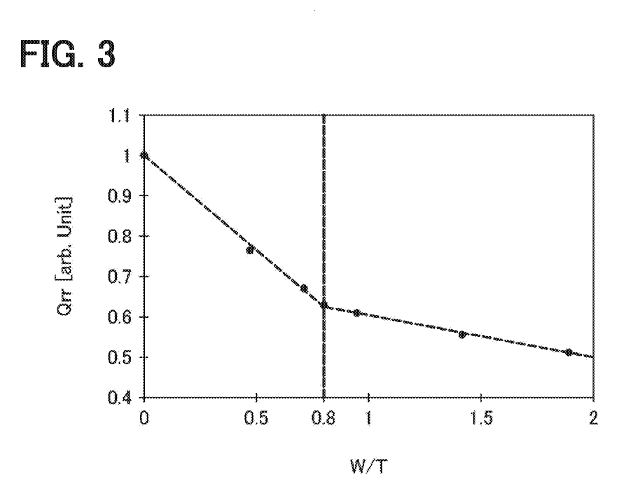

As described above, the hole injection restriction structure 31 is provided in the diode region 16 and the boundary region 15b, thereby making it possible to restrict the recovery current. FIG. 3 shows the results of measuring the recovery charge Qrr generated in semiconductor elements after manufacturing the semiconductor elements with different widths W of the boundary region 15b. The recovery charge Qrr is the total amount of charge that flows as a recovery current (that is, the value obtained by integrating the recovery current generated in the diode over time). The horizontal axis indicates the value W/T obtained by dividing the width W by the thickness T. As shown in FIG. 3, in the range of the value W/T from 0 to 0.8, the recovery charge Qrr decreases rapidly as the value W/T increases. In the range where the value W/T is 0.8 or more, the recovery charge Qrr decreases gradually as the value W/T increases. It can be seen from FIG. 3 that the recovery charge Qrr can be effectively reduced by setting the value W/T to 0.8 or more. As described above, in the semiconductor element 10 of the first embodiment, the value W/T is 0.8 or more, and therefore the recovery charge Qrr can be effectively reduced. The value W/T may be 8.0 or less (that is, the width W may be 8.0 times or less the thickness of the semiconductor substrate 12).

### Second Embodiment

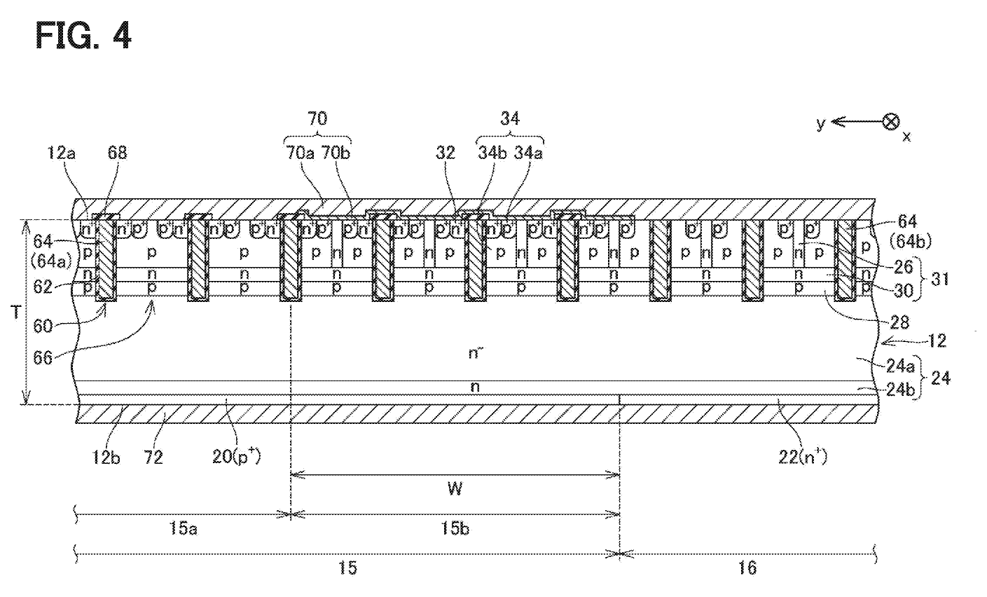

A switching element of a second embodiment shown in FIG. 4 differs from that of the first embodiment in that the emitter electrode 70 has a first metal layer 70a and a second metal layer 70b. Other configurations of the switching element of the second embodiment are the same as those of the first embodiment.

The first metal layer 70a and the second metal layer 70b are made of different metals. The second metal layer 70b covers the upper surface 12a within the boundary region 15b. The second metal layer 70b is in ohmic contact with the contact region 34a and the emitter region 32, and in Schottky contact with the pillar region 26 within the boundary region 15b. The first metal layer 70a covers the upper surface 12a in the diode region 16 and in the main region 15a. The first metal layer 70a covers the upper surface of the second metal layer 70b. The first metal layer 70a is in ohmic contact with the contact region 34a and the emitter region 32 in the diode region 16 and the main region 15a, and is in Schottky contact with the pillar region 26. The materials of the first metal layer 70a and the second metal layer 70b are selected so that a work function ϕBn2 at the interface between the second metal layer 70b and the pillar region 26 is lower than a work function ϕBn1 at the interface between the first metal layer 70a and the pillar region 26. For example, the first metal layer 70a may be made of an AlSi alloy, and the second metal layer 70b may be made of titanium.

In the second embodiment, the work function at the interface between the pillar region 26 and the emitter electrode 70 in the boundary region 15b is low, so the potential of the barrier region 30 in the boundary region 15b tends to be lower when the diode is on. Therefore, when the diode is in an on state, injection of holes into the drift region 24a can be more effectively restricted within the boundary region 15b. Therefore, the recovery current can be effectively restricted within the boundary region 15b.

In the second embodiment, the width W may be 80% or more of the thickness T, or may be less than 80% of the thickness T.

### Third Embodiment

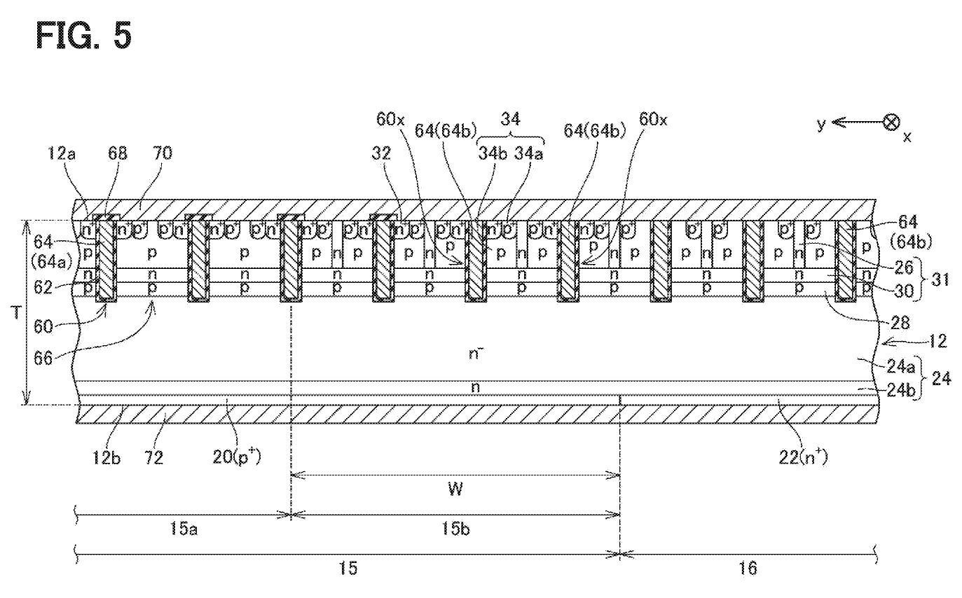

A switching element of a third embodiment shown in FIG. 5 differs from the first embodiment in that the trench electrode 64 arranged in some of the trenches 60x in the boundary region 15b is the dummy electrode 64b. Other configurations of the switching element of the third embodiment are the same as those of the first embodiment. This configuration makes it easier to stabilize the potential within the boundary region 15b.

In FIG. 5, the dummy electrode 64b is provided in some of the trenches 60 in the boundary region 15b, but the dummy electrode 64b may be provided in all of the trenches 60 in the boundary region 15b.

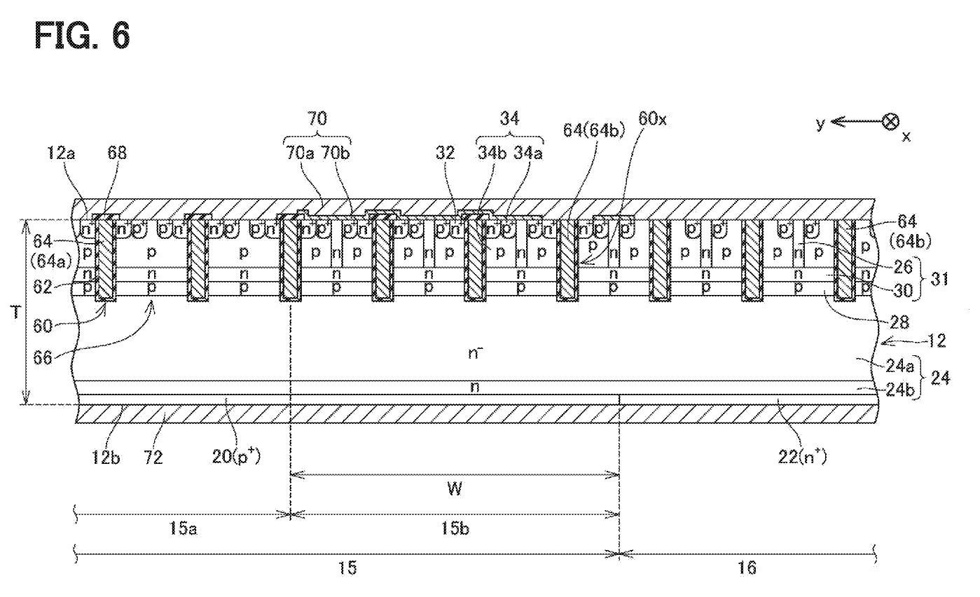

Moreover, as shown in FIG. 6, the second and third embodiments may be combined with each other.

### Fourth Embodiment

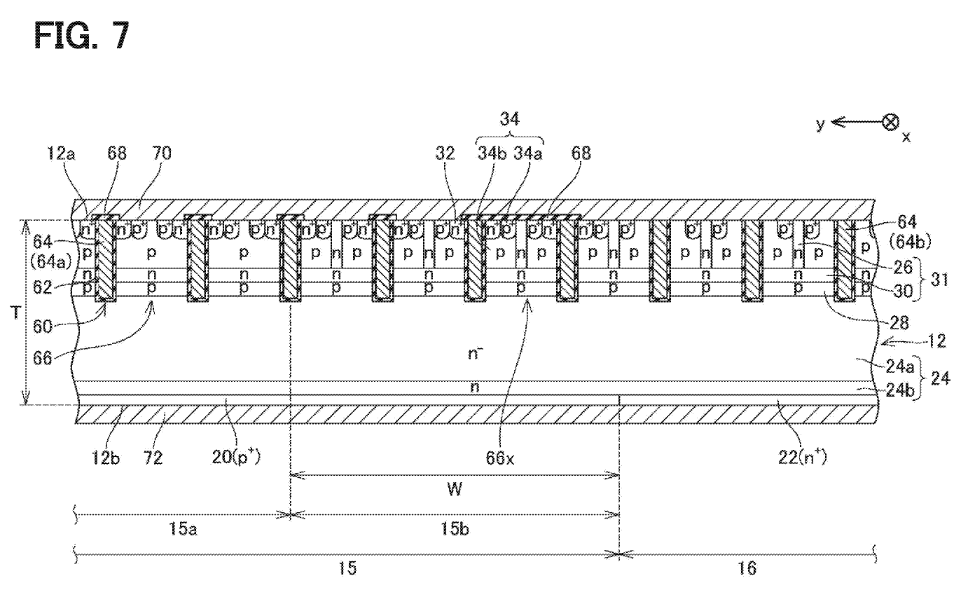

In a switching element of a fourth embodiment shown in FIG. 7, the upper surface 12a is covered with an interlayer insulating film 68 in a part of the inter-trench semiconductor region 66x in the boundary region 15b. In the inter-trench semiconductor region 66x covered with the interlayer insulating film 68, the upper body region 34 is insulated from the emitter electrode 70, and the potential of the upper body region 34 is floating. Hereinafter, a structure in which the upper body region 34 is insulated from the emitter electrode 70 by the interlayer insulating film 68 will be referred to as a floating structure. The other inter-trench semiconductor regions 66 in the boundary region 15b (i.e., the inter-trench semiconductor regions 66 that do not have a floating structure) have the hole injection restriction structure 31. Other configurations of the switching element of the fourth embodiment are the same as those of the first embodiment.

In the switching element of the fourth embodiment, when the diode is turned on, holes are not injected from the upper body region 34 into the drift region 24a in the inter-trench semiconductor region 66 having the floating structure. In addition, in other inter-trench semiconductor regions 66 in the boundary region 15b (i.e., inter-trench semiconductor regions 66 without a floating structure), the hole injection restriction structure 31 restricts the injection of holes from the upper body region 34 into the drift region 24a. Therefore, recovery current is unlikely to occur in the diode.

In the fourth embodiment, the width W may be 80% or more of the thickness T, or may be less than 80% of the thickness T.

Moreover, the fourth embodiment may be combined with at least one of the second and third embodiments.

In the first to fourth embodiments, the barrier region 30 is provided in each inter-trench semiconductor region 66 in the main region 15a, but the barrier region 30 may not be provided in each inter-trench semiconductor region 66 in the main region 15a.

In the first to fourth embodiments, the dummy electrode 64b is provided in the trench 60 in the diode region 16, but the gate electrode 64a may be provided in at least a part of the trenches 60 in the diode region 16.

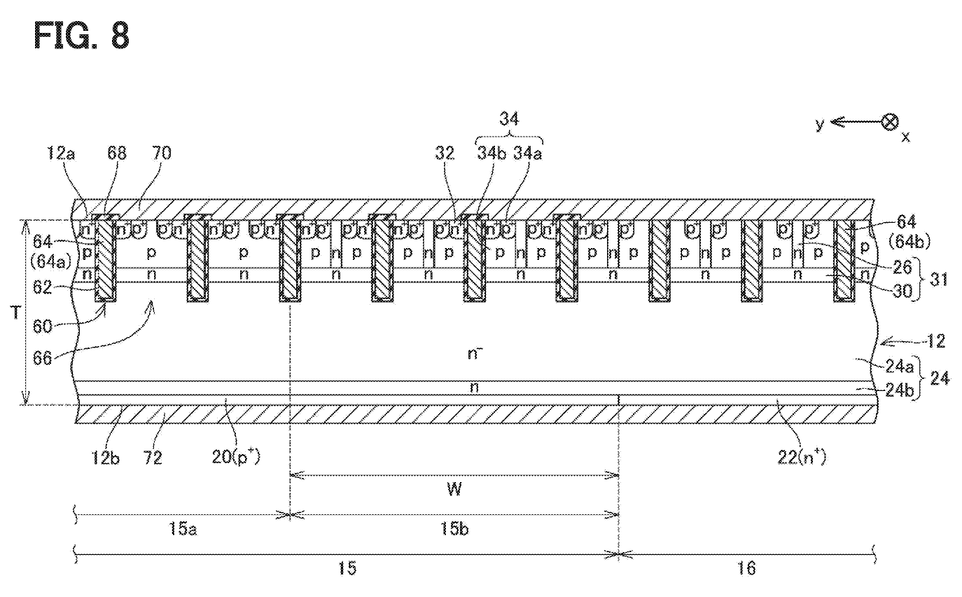

Although the semiconductor elements of the first to fourth embodiments have the lower body region 28, the techniques of the first to fourth embodiments may be applied to a semiconductor element that does not have the lower body region 28. For example, FIG. 8 shows a semiconductor element, in which the technique of the first embodiment is applied, that does not have a lower body region 28. As shown in FIG. 8, without the lower body region 28, the drift region 24a may be in contact with the barrier region 30 from below.

Although the embodiments have been described in detail above, these are merely examples and do not limit the scope of present disclosure. The techniques described in claims include various modifications of the specific examples illustrated above. The technical elements described in the present specification or the drawings exhibit technical usefulness alone or in various combinations, and are not limited to the

combinations described in the claims at the time of filing. In addition, the techniques illustrated in the present specification or drawings achieve plural objectives at the same time, and achieving one of the objectives itself has technical usefulness.

What is claimed is:

1. A semiconductor element comprising:
a semiconductor substrate;
an emitter electrode in contact with an upper surface of the semiconductor substrate; and
a collector electrode in contact with a lower surface of the semiconductor substrate, wherein
the semiconductor substrate includes:
a p-type collector region in contact with the collector electrode; and
an n-type cathode region in contact with the collector electrode,
when the semiconductor substrate is viewed in a thickness direction, a region overlapping with the collector region is an IGBT region, and a region overlapping with the cathode region is a diode region,
a first direction is defined along a boundary between the IGBT region and the diode region on the upper surface,
a second direction is defined to extend from the IGBT region toward the diode region on the upper surface,
a plurality of trenches are provided on the upper surface to extend in the first direction,
the plurality of trenches are arranged at interval in the second direction,
an inner surface of each of the plurality of trenches is covered with a trench insulating film,
a trench electrode is disposed in each of the plurality of trenches,
a plurality of inter-trench semiconductor regions interposed between the plurality of trenches are arranged in each of the IGBT region and the diode region,
each of the inter-trench semiconductor regions in the IGBT region and the diode region has a p-type body region in contact with the emitter electrode and the trench insulating film,
at least a portion of the inter-trench semiconductor region in the IGBT region has an n-type emitter region in contact with the emitter electrode and in contact with the trench insulating film above the body region,
the semiconductor substrate has an n-type drift region distributed across the IGBT region and the diode region and disposed below the body region,
a portion of the inter-trench semiconductor regions has a hole injection restriction structure including
an n-type barrier region in contact with the body region from below, and
a pillar region extending from the barrier region to the emitter electrode and in Schottky contact with the emitter electrode,
the IGBT region has
a main region formed by the plurality of inter-trench semiconductor regions in which the hole injection restriction structure is not provided, and
a boundary region formed by the plurality of inter-trench semiconductor regions located between the main region and the diode region,
the hole injection restriction structure is provided in each of the inter-trench semiconductor regions within the diode region and the boundary region, and
a width of the boundary region in the second direction is 80% or more of a thickness of the semiconductor substrate.

2. The semiconductor element according to claim 1, wherein a work function at an interface between the pillar region and the emitter electrode in the boundary region is lower than a work function at an interface between the pillar region and the emitter electrode in the diode region.

3. The semiconductor element according to claim 1, wherein
the trench electrode in the main region is a gate electrode, and
at least one trench electrode in the boundary region is a dummy electrode connected to the emitter electrode.

4. A semiconductor element comprising:
a semiconductor substrate;
an emitter electrode in contact with an upper surface of the semiconductor substrate; and
a collector electrode in contact with a lower surface of the semiconductor substrate, wherein
the semiconductor substrate includes:
a p-type collector region in contact with the collector electrode; and
an n-type cathode region in contact with the collector electrode,
when the semiconductor substrate is viewed in a thickness direction, a region overlapping with the collector region is an IGBT region, and a region overlapping with the cathode region is a diode region,
a first direction is defined along a boundary between the IGBT region and the diode region on the upper surface,
a second direction is defined to extend from the IGBT region toward the diode region on the upper surface,
a plurality of trenches are provided on the upper surface to extend in the first direction,
the plurality of trenches are arranged at interval in the second direction,
an inner surface of each of the plurality of trenches is covered with a trench insulating film,
a trench electrode is disposed in each of the plurality of trenches,
a plurality of inter-trench semiconductor regions interposed between the plurality of trenches are arranged in each of the IGBT region and the diode region,
each of the inter-trench semiconductor regions in the IGBT region and the diode region has a p-type body region in contact with the emitter electrode and the trench insulating film,
at least a portion of the inter-trench semiconductor region in the IGBT region has an n-type emitter region in contact with the emitter electrode and in contact with the trench insulating film above the body region,
the semiconductor substrate has an n-type drift region distributed across the IGBT region and the diode region and disposed below the body region,
a portion of the inter-trench semiconductor regions has a hole injection restriction structure including
an n-type barrier region in contact with the body region from below, and
a pillar region extending from the barrier region to the emitter electrode and in Schottky contact with the emitter electrode,
the IGBT region has
a main region formed by the plurality of inter-trench semiconductor regions in which the hole injection restriction structure is not provided, and
a boundary region formed by the plurality of inter-trench semiconductor regions located between the main region and the diode region,
the hole injection restriction structure is provided in each of the inter-trench semiconductor regions within the diode region and the boundary region, and
a work function at an interface between the pillar region and the emitter electrode in the boundary region is lower than a work function at an interface between the pillar region and the emitter electrode in the diode region.

5. A semiconductor element comprising:
a semiconductor substrate;
an emitter electrode in contact with an upper surface of the semiconductor substrate; and
a collector electrode in contact with a lower surface of the semiconductor substrate, wherein
the semiconductor substrate includes:
a p-type collector region in contact with the collector electrode; and
an n-type cathode region in contact with the collector electrode,
when the semiconductor substrate is viewed in a thickness direction, a region overlapping with the collector region is an IGBT region, and a region overlapping with the cathode region is a diode region,
a first direction is defined along a boundary between the IGBT region and the diode region on the upper surface,
a second direction is defined to extend from the IGBT region toward the diode region on the upper surface,
a plurality of trenches are provided on the upper surface to extend in the first direction,
the plurality of trenches are arranged at interval in the second direction,
an inner surface of each of the plurality of trenches is covered with a trench insulating film,
a trench electrode is disposed in each of the plurality of trenches,
a plurality of inter-trench semiconductor regions interposed between the plurality of trenches are arranged in each of the IGBT region and the diode region,
each of the inter-trench semiconductor regions in the IGBT region and the diode region has a p-type body region in contact with the emitter electrode and the trench insulating film,
at least a portion of the inter-trench semiconductor region in the IGBT region has an n-type emitter region in contact with the emitter electrode and in contact with the trench insulating film above the body region,
the semiconductor substrate has an n-type drift region distributed across the IGBT region and the diode region and disposed below the body region,
a portion of the inter-trench semiconductor regions has a hole injection restriction structure including
an n-type barrier region in contact with the body region from below, and
a pillar region extending from the barrier region to the emitter electrode and in Schottky contact with the emitter electrode,
a portion of the inter-trench semiconductor regions has a floating structure in which the upper surface is covered with an interlayer insulating film,
the IGBT region has
a main region formed by the plurality of inter-trench semiconductor regions in which the hole injection restriction structure is not provided, and
a boundary region formed by the plurality of inter-trench semiconductor regions located between the main region and the diode region,
each of the inter-trench semiconductor regions in the diode region has the hole injection restriction structure, and
each of the inter-trench semiconductor regions in the boundary region has at least one of the hole injection restriction structure and the floating structure.
